(19) United States
(12) Patent Application Publication
(10) Pub. No.: US 2002/0168840 A1
(43) Pub. Date: Nov. 14, 2002

(54) Deposition of tungsten silicide films

(75) Inventors: Soonil Hong, Mountain View, CA (US); Hyungsuk Alexander Yoon, Santa Clara, CA (US); Chiliang Chen, Sunnyvale, CA (US); Kimberly Branshaw, Santa Clara, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/853,349

(22) Filed: May 11, 2001

(51) Int. Cl. H01L 21/20

(52) U.S. Cl. 438/584

(57) ABSTRACT

A method of forming tungsten suicide (WSiₓ) films is provided. The tungsten suicide (WSiₓ) films are formed by reacting a tungsten source with a silicon source at a temperature greater than about 600° C. The as-deposited tungsten suicide (WSiₓ) layer has a resistivity less than about 60 μΩ-cm.

### BACKGROUND OF THE DISCLOSURE

1. Field of the Invention

The invention relates to a method of tungsten silicide film deposition and, more particularly, to a method of forming a low resistivity tungsten silicide film.

2. Description of the Background Art

In the manufacture of integrated circuits, there is a growing demand for low resistivity electrodes (e. g., resistivities of less than about 75 μΩ-cm) suitable for use as gate interconnect metallization. Tungsten silicide (WSiₓ) films have been suggested as low resistivity electrodes for gate interconnect metallization.

The tungsten silicide layers may be formed using chemical vapor deposition (CVD) techniques. For example, tungsten silicide may be formed by reacting a tungsten source (e. g., tungsten hexafluoride (WF₆)) with a silicon source (e. g., dichlorosilane (SiH₂Cl₂)) at temperatures less than about 580° C. However, as-deposited tungsten silicide (WSiₓ) films formed by reacting tungsten hexafluoride (WF₆) with dichlorosilane (SiH₂Cl₂) at temperatures less than about 580° C. typically have high resistivities (e. g., resistivity of greater than 400 μΩ-cm) making them unsuitable for use as low resistivity electrodes on gate interconnects. The resistivity of the as-deposited WSiₓ films may be reduced using a furnace annealing process. However, after furnace annealing, the resistivity of the tungsten silicide films is still greater than about 100 μΩ-cm to about 150 μΩ-cm.

Therefore, a need exists in the art for a method of forming low resistivity tungsten silicide films.

### SUMMARY OF THE INVENTION

A method of forming tungsten silicide (WSiₓ) films is provided. The tungsten silicide (WSiₓ) films are formed by reacting a tungsten source with a silicon source at a temperature greater than about 600° C. The as-deposited tungsten silicide (WSiₓ) layer has a resistivity less than about 60 μΩ-cm, as well as a polycrystalline structure.

The tungsten silicide film formation is compatible with integrated circuit fabrication processes. In one integrated circuit fabrication process, the tungsten silicide film is used as gate interconnection metallization. For a gate metallization process, a preferred process sequence includes providing a substrate having a polysilicon gate thereon surrounded by a dielectric material (e. g., an oxide). Tungsten silicide interconnection metallization is formed on the polysilicon gate by reacting a tungsten source with a silicon source at a temperature greater than about 600° C. The as-deposited tungsten silicide (WSiₓ) interconnection metallization has a resistivity less than about 60 μΩ-cm.

### BRIEF DESCRIPTION OF THE DRAWINGS

The teachings of the present invention can be readily understood by considering the following detailed description in conjunction with the accompanying drawings, in which:

FIG. 1 depicts a schematic illustration of an apparatus that can be used for the practice of this invention;

FIG. 2 depicts a schematic cross-sectional view of a chemical vapor deposition (CVD) chamber;

FIG. 3 depicts a schematic cross-sectional view of a rapid thermal processor (RTP) chamber;

FIGS. 4a-4c depict schematic cross-sectional views of an integrated circuit structure at different stages of a fabrication sequence incorporating a tungsten silicide (WSiₓ) film; and

FIG. 5 illustrates tungsten silicide layer resistivity plotted as a function of deposition temperature during layer formation.

### DETAILED DESCRIPTION

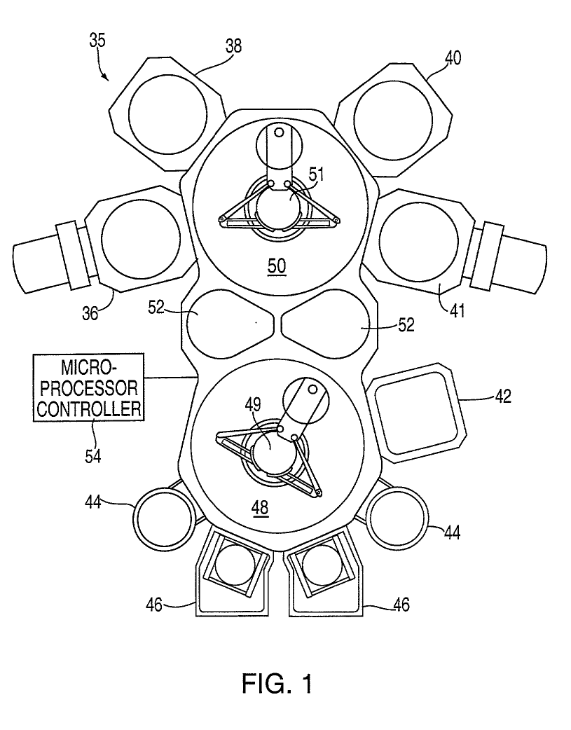

FIG. 1 is a schematic representation of a wafer processing system 35 that can be used to perform tungsten silicide (WSiₓ) film formation in accordance with embodiments described herein. The wafer processing system 35 typically comprises process chambers 36, 38, 40, 41, degas chambers 44, load-lock chambers 48, 50, pass-through chambers 52, a microprocessor controller 54, along with other hardware components such as power supplies (not shown) and vacuum pumps (not shown). An example of such a wafer processing system 35 is an ENDURA® System, commercially available from Applied Materials, Inc., Santa Clara, Calif.

Details of the wafer processing system 35 are described in commonly assigned U.S. Pat. No. 5,186,718, entitled, “Staged-Vacuum Substrate Processing System and Method”, issued on Feb. 16, 1993, and is hereby incorporated by reference. The salient features of the wafer processing system 35 are briefly described below.

The wafer processing system includes two transfer chambers 48, 50, each containing a transfer robot 49, 51. The transfer chambers 48, 50 are separated one from the other by pass-through chambers 52.

Transfer chamber 48 is coupled to load-lock chambers 46, degas chambers 44, pre-clean chamber 42, and pass-through chambers 52. Substrates (not shown) are loaded into the wafer processing system 35 through load-lock chambers 46. Thereafter, the substrates are sequentially degassed and cleaned in degas chambers 44 and the pre-clean chamber 42, respectively. The transfer robot 49 moves the substrate between the degas chambers 44 and the pre-clean chamber 42.

Transfer chamber 50 is coupled to a cluster of process chambers 36, 38, 40, 41. The cleaned substrates are moved from transfer chamber 48 into transfer chamber 50 via pass-through chambers 52. Thereafter, transfer robot 51 moves the substrates between one or more of the process chambers 36, 38, 40, 41.

The process chambers 36, 38, 40, 41 are used to perform various integrated circuit fabrication sequences. For example, process chambers 36, 38, 40, 41 may include chemical vapor deposition (CVD) chambers, rapid thermal process (RTP) chambers, anti-reflective coating (ARC) chambers, physical vapor deposition (PVD) chambers, and ionized metal plasma physical vapor deposition (IMP PVD) chambers, among others.

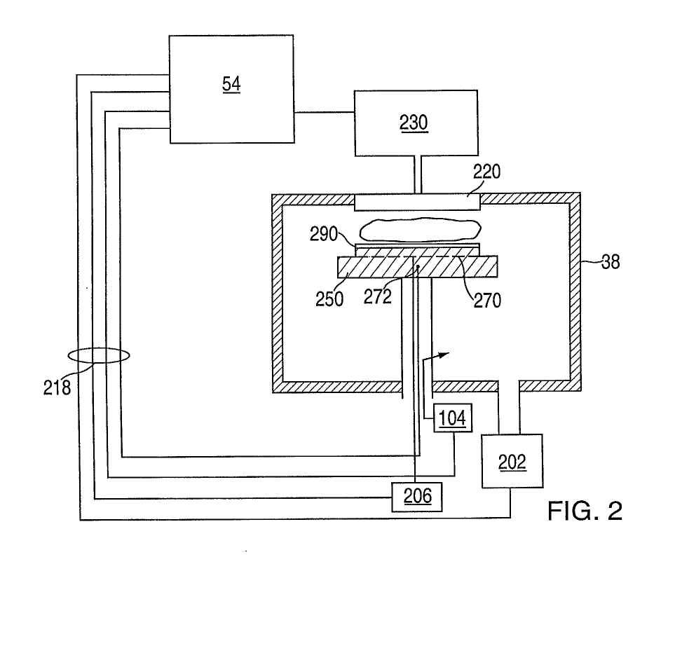

FIG. 2 depicts a schematic cross-sectional view of a chemical vapor deposition (CVD) process chamber 38 of wafer processing system 35. Examples of such CVD chambers 38 include WXZ® chambers and PRECISION 5000® chambers, commercially available from Applied Materials, Inc., located in Santa Clara, Calif.

The CVD chamber 38 generally houses a support pedestal 250, which is used to support a substrate, such as a semiconductor wafer 290. The support pedestal 250 is movable in a vertical direction inside the CVD chamber 38 using a displacement mechanism (not shown).

Depending on the specific CVD process, the semiconductor wafer 290 can be heated to some desired temperature prior to or during tungsten silicide (WSiₓ) film deposition. For example, referring to FIG. 1, the support pedestal 250 may be resistively heated using an embedded heater element 270. The support pedestal 250 may be resistively heated by applying an electric current from an AC power supply 206 to the heater element 270. The semiconductor wafer 290 is, in turn, heated by the pedestal 250.

A temperature sensor 272, such as a thermocouple, is also embedded in the support pedestal 250 to monitor the temperature of the pedestal 250 in a conventional manner. The measured temperature can be used in a feedback loop to control the power supplied to the heater element 270, such that the wafer can be maintained or controlled at a desired temperature which is suitable for the particular process application. The support pedestal 250 may optionally be heated using radiant heat (not shown).

A vacuum pump 202, is used to evacuate the CVD chamber 38 and to maintain the proper gas flows and pressure inside the CVD chamber 38. A showerhead 220, through which process gases are introduced into the CVD chamber 38, is located above the support pedestal 250. The showerhead 220 is coupled to a gas panel 230, which controls and supplies various gases provided to the CVD chamber 38.

Proper control and regulation of the gas flows through the gas panel 230 is performed by mass flow controllers (not shown) and a microprocessor controller 54. The showerhead 220 allows process gases from the gas panel 230 to be uniformly introduced and distributed in the CVD chamber 38.

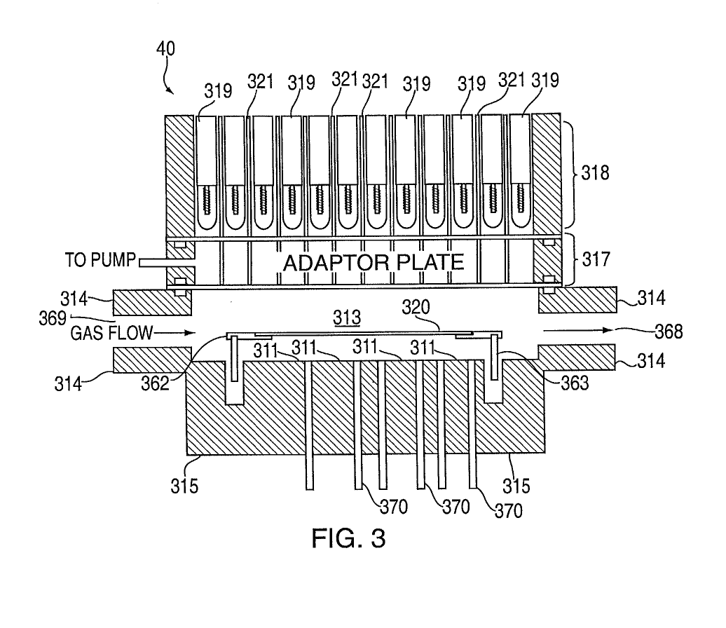

FIG. 3 depicts a schematic cross-sectional view of a rapid thermal processor (RTP) chamber 40 of wafer processing system 35. An example of a RTP chamber 40 is a RADIANCE® chamber, commercially available from Applied Materials, Inc., Santa Clara, Calif.

The RTP chamber 40 includes sidewalls 314, a bottom 315, and a window assembly 317. The sidewalls 314 and the bottom 315 generally comprise a metal such as, for example, stainless steel. The upper portions of sidewalls 314 are sealed to window assembly 317 by o-rings 316. A radiant energy assembly 318 is positioned over and coupled to window assembly 317. The radiant energy assembly 318 includes a plurality of lamps 319 each mounted to a light pipe 321.

The RTP chamber 40 houses a substrate 320 supported around its perimeter by a support ring 362 made of, for example, silicon carbide. The support ring 362 is mounted on a rotatable cylinder 363. The rotatable cylinder causes the support ring 362 and the substrate to rotate within the RTP chamber 40.

The bottom 315 of RTP chamber 40 includes a gold-coated top surface 311, which reflects light energy onto the backside of the substrate 320. Additionally, the RTP chamber 40 includes a plurality of temperature probes 370 positioned through the bottom 315 of RTP chamber 40 to detect the temperature of the substrate 320.

A gas inlet 369 through sidewall 314 provides process gases to the RTP chamber 40. A gas outlet 368 positioned through sidewall 314 opposite to gas inlet 369 removes process gases from the RTP chamber 40. The gas outlet 368 is coupled to a pump system (not shown) such as a vacuum source. The pump system exhausts process gases from the RTP chamber 40 and maintains a desired pressure therein during processing.

The radiant energy assembly 318 preferably is configured so the lamps 319 are positioned in a hexagonal array or in a “honeycomb” arrangement, above the surface area of the substrate 320 and the support ring 362. The lamps 319 are grouped in zones that may be independently controlled, to uniformly heat the substrate 320.

The window assembly 317 includes a plurality of short light pipes 341 that are aligned to the light pipes 321 of the radiant energy assembly 318. Radiant energy from the lamps 321 is provided via light pipes 321, 341 to the process region 313 of RTP chamber 40.

Referring to FIG. 1, the CVD process chamber 38 and the RTP chamber 40 as described above are each controlled by a microprocessor controller 54. The microprocessor controller 54 may be one of any form of general purpose computer processor (CPU) that can be used in an industrial setting for controlling process chambers as well as sub-processors. The computer may use any suitable memory, such as random access memory, read only memory, floppy disk drive, hard drive, or any other form of digital storage, local or remote. Various support circuits may be coupled to the CPU for supporting the processor in a conventional manner. Software routines as required may be stored in the memory or executed by a second CPU that is remotely located.

The process sequence routines are executed after the substrate is positioned on the pedestal. The software routines, when executed, transform the general purpose computer into a specific process computer that controls the chamber operation so that a chamber process is performed. Alternatively, the software routines may be performed in hardware, as an application specific integrated circuit or other type of hardware implementation, or a combination of software and hardware.

### Tungsten Silicide (WSiₓ) Film Deposition

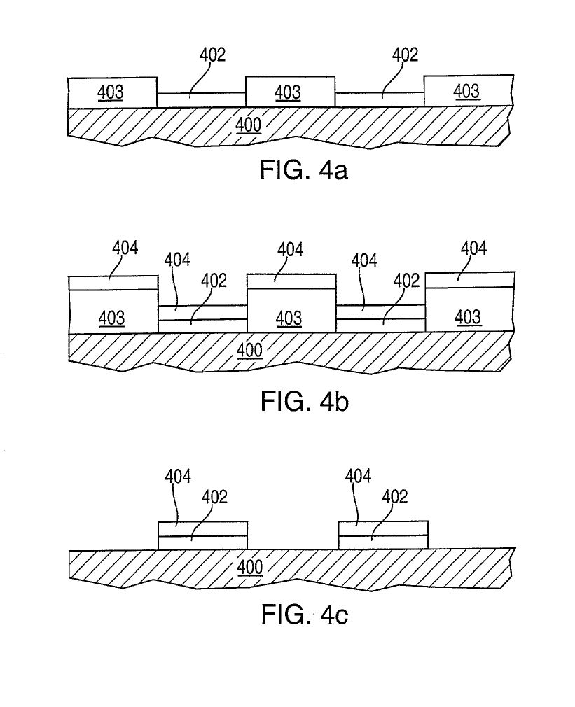

FIGS. 4a-4c illustrate an integrated circuit structure at different stages of a fabrication sequence, incorporating a tungsten suicide (WSiₓ) layer as interconnect metallization. In general, the substrate 400 refers to any workpiece upon which film processing is performed, and a substrate structure 450 is used to generally denote the substrate 400 as well as other material layers formed on the substrate 400.

Depending on the specific stage of processing, the substrate 400 may be a silicon semiconductor wafer, or other material layer, which has been formed on the wafer. FIG. 4a, for example, shows a cross-sectional view of a silicon substrate 400, having polysilicon gates 402 thereon surrounded by dielectric material 403. In this particular illustration, the dielectric material 403 may be an oxide (e. g., silicon dioxide, fluorosilicate glass (FSG), undoped silicate glass (USG)). The dielectric material 403 has been conventionally formed and patterned to provide contact holes having sidewalls, and extending to the top surface of the polysilicon gates 402.

FIG. 4b depicts a tungsten silicide (WSiₓ) interconnect metallization 404 filling the contact holes formed over the polysilicon gates 402. The tungsten silicide (WSiₓ) interconnect metallization 404 is formed by reacting a tungsten source with a silicon source.

Tungsten hexafluoride (WF₆), among others may be used for the tungsten source. Chlorosilane (SiH₃Cl), dichlorosilane (SiH₂Cl₂), trichlorosilane (SiHCl₃), among others, and combinations thereof may be used for the silicon source. Carrier gases such as argon (Ar), helium (He), neon (Ne), and nitrogen (N₂), among others may be mixed with the tungsten source and/or the silicon source.

In general, the following deposition process parameters can be used to form the tungsten silicide (WSiₓ) film 404 in a deposition chamber similar to that shown in FIG. 2. The process parameters range from a wafer temperature greater than about 600° C., a chamber pressure of about 0.5 torr to about 5 torr, a tungsten source:silicon source flow ratio of greater than about 0.045:1, and a carrier gas flow rate of about 100 sccm to about 1000 sccm. The above process parameters provide a deposition rate for the tungsten silicide (WSiₓ) film in a range of about 50 Å/min to about 400 Å/min when implemented on a 200 mm (millimeter) substrate in a deposition chamber available from Applied Materials, Inc., located in Santa Clara, Calif.

Other deposition chambers are within the scope of the invention, and the parameters listed above may vary according to the particular deposition chamber used to form the tungsten silicide (WSiₓ) film. For example, other deposition chambers may have a larger (e. g., configured to accommodate 300 mm substrates) or smaller volume, requiring gas flow rates that are larger or smaller than those recited for deposition chambers available from Applied Materials, Inc.

The reaction of the tungsten source with the silicon source at a temperature greater than about 600° C. advantageously forms tungsten silicide (WSiₓ) films having resistivities less than about 60 μΩ-cm. It is believed that reacting the tungsten source with the silicon source at a temperature greater than about 600° C. forms tungsten silicide (WSiₓ) layers having a polycrystalline structure rather than an amorphous structure. Polycrystalline tungsten silicide (WSiₓ) layers typically have resistivities less than about 60 μΩ-cm.

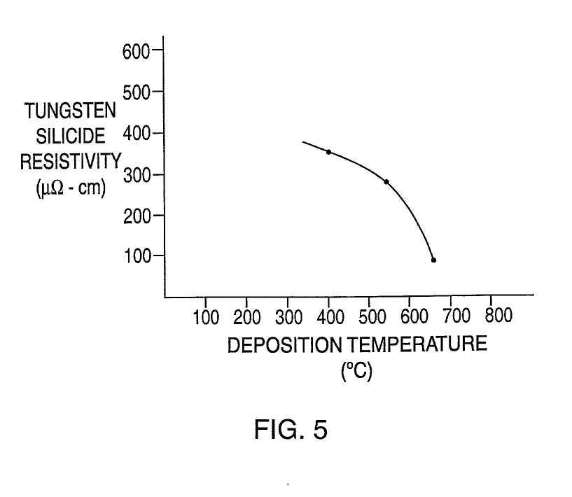

Referring to FIG. 5, tungsten silicide layer resistivity is plotted as a function of deposition temperature during layer formation. At deposition temperatures less than about 550° C. tungsten silicide layer resistivities are greater than about 200 μΩ-cm, which is indicative of the formation of layers having amorphous structures. Whereas, at deposition temperatures greater than about 600° C. tungsten suicide layer resistivities are less than about 60μΩ-cm, which is indicative of the formation of layers having polysilicon structures.

Additionally, the reaction of the tungsten source with the silicon source at a tungsten source : silicon source flow ratio of greater than about 0.045:1 is also believed to contribute to the lower resistivity of the as-deposited tungsten silicide (WSiₓ) films, by forming tungsten-rich layers.

After the tungsten silicide (WSiₓ) layer 404 is formed, it may optionally be furnace annealed. It is believed that furnace annealing the tungsten silicide (WSiₓ) layer may further lower the resistivity thereof, by densifying the layer and reducing the concentration impurities therein (e. g., fluorine from the tungsten hexafluoride and/or chlorine from the dichlorosilane).

The tungsten silicide (WSiₓ) layer is preferably furnace annealed using a nitrogen source. Ammonia (NH₃), nitrogen (N₂), and mixtures thereof, among others may be used for the nitrogen source.

In general, the following process parameters may be used to furnace anneal the tungsten silicide (WSiₓ) layer 404 in a rapid thermal process (RTF) chamber similar to that shown in FIG. 3. The process parameters range from an annealing temperature of about 600° C. to about 1100° C., a chamber pressure of about 0.5 torr to about 100 torr, and a nitrogen source flow rate of about 100 sccm to about 5 slm. The tungsten silicide (WSiₓ) layer may be annealed for up to about 60 minutes.

Referring to FIG. 4c, after the tungsten silicide (WSiₓ) layer 404 is formed on the substrate 400 and optionally annealed, the surrounding dielectric material 403, with tungsten silicide (WSiₓ) 404 thereon may optionally be removed. The dielectric material 403 and tungsten silicide (WSiₓ) 404 may be removed by etching the dielectric material 403 using an appropriate etchant.

Although several preferred embodiments which incorporate the teachings of the present invention have been shown and described in detail, those skilled in the art can readily devise many other varied embodiments that still incorporate these teachings.

What is claimed is:

1. A method of thin film deposition, comprising:
(a) positioning a substrate in a deposition chamber;
(b) providing a gas mixture to the deposition chamber, wherein the gas mixture comprises a tungsten source and a silicon source; and
(c) reacting the gas mixture at a temperature greater than about 600° C. to form a polycrystalline tungsten silicide (WSiₓ) layer on the substrate.

2. The method of claim 1 wherein the tungsten source is tungsten hexafluoride (WF₆).

3. The method of claim 1 wherein the silicon source is selected from the group consisting of chlorosilane (SiH₃Cl), dichlorosilane (SiH₂Cl₂), trichlorosilane (SiHCl₃), and combinations thereof.

4. The method of claim 1 wherein the tungsten source:silicon source flow ratio is greater than about 0.045:1.

5. The method of claim 1 wherein the deposition chamber is maintained at a pressure in a range of about 0.5 torr to about 5 torr.

6. The method of claim 1, further comprising the step of annealing the polycrystalline tungsten silicide (WSiₓ) layer formed on the substrate.

7. The method of claim 6 wherein the polycrystalline tungsten silicide (WSiₓ) layer is annealed by positioning the substrate having the polycrystalline tungsten silicide (WSiₓ) layer thereon in a process chamber;
providing a nitrogen source to the process chamber; and
heating the substrate to a temperature within a range of about ₆₀₀° C. to about 1100° C.

8. The method of claim 7 wherein the nitrogen source is selected from the group consisting of ammonia (NH₃) and nitrogen (N₂).

9. A method of forming a device, comprising:
(a) positioning a substrate in a deposition chamber;
(b) providing a gas mixture to the deposition chamber, wherein the gas mixture comprises a tungsten source and a silicon source; and
(c) reacting the gas mixture at a temperature greater than about 600° C. to form a polycrystalline tungsten silicide (WSiₓ) layer on the substrate.

10. The method of claim 9 wherein the tungsten source is tungsten hexafluoride (WF₆).

11. The method of claim 9 wherein the silicon source is selected from the group consisting of chlorosilane (SiH₃Cl), dichlorosilane (SiH₂Cl₂), trichlorosilane (SiHCl₃), and combinations thereof.

12. The method of claim 9 wherein the tungsten source:silicon source flow ratio is greater than about 0.045:1.

13. The method of claim 9 wherein the deposition chamber is maintained at a pressure in a range of about 0.5 torr to about 5 torr.

14. The method of claim 9, further comprising the step of annealing the polycrystalline tungsten silicide (WSiₓ) layer formed on the substrate.

15. The method of claim 14 wherein the polycrystalline tungsten silicide (WSiₓ) layer is annealed by positioning the substrate having the polycrystalline tungsten suicide (WSiₓ) layer thereon in a process chamber;
providing a nitrogen source to the process chamber; and
heating the substrate to a temperature within a range of about 600° C. to about 1100° C.

16. The method of claim 15 wherein the nitrogen source is selected from the group consisting of ammonia (NH₃) and nitrogen (N₂).

17. A method of thin film deposition, comprising:
(a) positioning a substrate in a deposition chamber;
(b) providing a gas mixture to the deposition chamber, wherein the gas mixture comprises a tungsten source and a silicon source; and
(c) reacting the gas mixture at a temperature greater than about 600° C. to form a polycrystalline tungsten suicide (WSiₓ) layer on the substrate having a resistivity less than about 60 μΩ-cm.

18. A method of forming a device, comprising:
(a) positioning a substrate in a deposition chamber;
(b) providing a gas mixture to the deposition chamber, wherein the gas mixture comprises a tungsten source and a silicon source; and
(c) reacting the gas mixture at a temperature greater than about 600° C. to form a tungsten suicide (WSiₓ) layer on the substrate having a resistivity less than about 60 μΩ-cm.

19. A method of thin film deposition, comprising:
(a) positioning a substrate in a deposition chamber;
(b) providing a gas mixture to the deposition chamber, wherein the gas mixture comprises a tungsten hexafluoride (WF₆) and a silicon source selected from the group consisting of chlorosilane (SiH₃Cl), dichlorosilane (SiH₂Cl₂), trichlorosilane (SiHCl₃), and combinations thereof, wherein the tungsten hexafluoride: silicon source flow ratio is greater than about 0.045:1; and
(c) reacting the gas mixture at a temperature greater than about 600° C. to form a polycrystalline tungsten silicide (WSiₓ) layer on the substrate having a resistivity less than about 60 μΩ-cm.
